(19) United States
(12) Patent Application Publication
(10) Pub. No.: US 2009/0008771 A1
(43) Pub. Date: Jan. 8, 2009

(54) SEMICONDUCTOR MODULE DEVICE, METHOD OF MANUFACTURING THE SAME, FLAT PANEL DISPLAY, AND PLASMA DISPLAY PANEL

(75) Inventors: Michiharu Torii, Shiga (JP); Nozomi Shimoishizaka, Kyoto (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 12/166,530

(22) Filed: Jul. 2, 2008

(30) Foreign Application Priority Data
Jul. 6, 2007 (JP) 2007-177843

(51) Int. Cl. H01L 23/36; H01L 21/58

(52) U.S. Cl. 257/713; 438/122; 257/E21.505; 257/E23.101

(57) ABSTRACT

Metal foil 1 is provided on a surface of a flexible substrate 4 so as to be thermally connected to a semiconductor chip 5, the surface being opposed to the other surface that is in contact with a radiator 2, and the metal foil 1 is screwed to the radiator 2 with fastening screws 3a. Thus heat generated from the semiconductor chip 5 is transmitted from one surface of the semiconductor chip 5 to the radiator 2 through a heat dissipating material 5b, and the heat is transmitted from the other surface of the semiconductor chip 5 to the radiator 2 through the metal foil 1, achieving heat transfer from the two surfaces of the semiconductor chip 5 to the radiator 2. Thus it is possible to improve heat dissipation without considerably increasing the number of components or a set weight.

### FIELD OF THE INVENTION

The present invention relates to a semiconductor module device for adding a heat dissipating structure to a driving semiconductor integrated circuit (IC) chip (hereinafter, will be referred to as a semiconductor chip) in a flat panel display such as a color plasma display panel, a method of manufacturing the same, a flat panel display including the semiconductor module device, and a plasma display panel.

### BACKGROUND OF THE INVENTION

In flat panel display technology, plasma displays have received attention because display can be provided at higher speeds than liquid crystal panels with wide viewing angles, the sizes can be easily increased, and high display quality can be obtained by a self-luminous display system. Further, a number of semiconductor chips have become necessary as finer pitches are provided for high-definition screens.

Such semiconductor chips require high-density packaging, and a large load applied to the semiconductor chips during image display causes an extremely high temperature in semiconductor module devices. In a generally known heat dissipating structure, a semiconductor chip mounted for high-density packaging on a flexible substrate is sandwiched by a heat dissipating sheet, the heat dissipating sheet is sandwiched by an integrated metal cover and the like, and the metal cover is fastened with screws and the like on a metal chassis for fixing a panel. In this heat dissipating structure, heat from the semiconductor chip is dissipated to the metal cover through the heat dissipating sheet, causing a large thermal resistance from the semiconductor chip to the metal chassis. Thus it is difficult to sufficiently dissipate heat from the semiconductor chip. Although the thermal resistance can be reduced by reducing the thickness of the heat dissipating sheet, the thickness cannot be considerably reduced because a thin heat dissipating sheet may break the semiconductor chip during handling. Another problem is that the metal cover and the semiconductor chip are hard to bond with an automatic machine in a worksite because the radiating sheet is made of a soft material such as silicon.

In order to solve these problems, the configurations of module devices (hereinafter, will be referred to as semiconductor module devices) have been adopted as disclosed in Japanese Patent Laid-Open No. 2005-338706 in which a radiator is attached to a semiconductor chip. FIGS. 13, 14 and 15 show a known semiconductor module device. FIG. 13 is a sectional view showing the configuration of the semiconductor module device of the prior art and is a sectional view taken along line A-A′ of FIG. 15. FIG. 14 is a part exploded perspective view showing the configuration of the semiconductor module device of the prior art. FIG. 15 is an external perspective view showing the assembled semiconductor module device of the prior art.

In FIGS. 13, 14 and 15, in the semiconductor module device of the prior art, a flexible substrate 4 having a semiconductor chip 5 mounted thereon and a radiator 2 are fixed to each other with an adhesive 6. The radiator 2 is screwed to metal chassis receiving parts 7 of a flat panel display and dissipates heat to a chassis.

To be specific, the joined part of the flexible substrate 4 and the semiconductor chip 5 is covered with a chip protecting resin 5a. The radiator 2 has a storage recessed portion 2a for the semiconductor chip 5. The radiator 2 and the flexible substrate 4 are bonded to each other with the adhesive 6 provided around the storage recessed portion 2a. The backside of the semiconductor chip 5 is in contact with the storage recessed portion 2a of the radiator 2 via silicone grease acting as a heat dissipating material 5b or a heat dissipating sheet and the like. With this configuration, heat generated on the semiconductor chip 5 can be efficiently released to the radiator 2 through the heat dissipating material 5b. In another known configuration (not shown), a semiconductor module device is screwed while separated by a metal chassis for supporting a flat panel display.

### DISCLOSURE OF THE INVENTION

In semiconductor module devices configured thus, however, as high-definition plasma displays have been provided in recent years, the number of output channels has been increased for each semiconductor chip to reduce the number of components. Accordingly, an amount of heat generated from each semiconductor chip has increased. Thus in order to prevent heat generation from causing a malfunction or a break on semiconductor chips, it has become necessary to sufficiently dissipate heat from the semiconductor chips. Further, in order to reduce the amount of heat generated from a semiconductor chip, a driving load has been reduced by reexamining the image control of a display device. When the configuration of a radiator remains the same, the amount of heat dissipation is limited and thus it has become necessary to reexamine the method and configuration of heat dissipation. For example, a large fin may be added to the radiator or the radiator may be forcefully air-cooled using a fan. Such a configuration disadvantageously increases the number of components and a set weight.

The present invention is devised to solve the aforementioned problem. An object of the present invention is to improve heat dissipation while keeping a light weight and low cost without dramatically changing an existing configuration in the semiconductor module device of a semiconductor chip used for a flat panel display such as a color plasma display.

In order to attain the object, a semiconductor module device of the present invention has a heat dissipating structure, the semiconductor module device including: a flexible substrate on which a wiring pattern connected to an external terminal is formed; an insulating resist for protecting wiring; a semiconductor chip mounted on the flexible substrate while molded with chip protecting resin so as to be electrically connected to the wiring pattern; metal foil formed in contact with the chip protecting resin for molding the semiconductor chip and with at least a part of the insulating resist; a radiator which has a storage recessed portion and is bonded to the flexible substrate so as to connect the semiconductor chip to the storage recessed portion via a heat dissipating material; and screws for screwing the metal foil and the radiator with thermal bonding.

The semiconductor module device further includes a region electrically isolated from the wiring pattern, on the same surface as the wiring pattern of the flexible substrate, wherein the metal foil is disposed in the region, and the metal foil is bonded on the chip protecting resin for molding the semiconductor chip and on at least a part of the insulating resist by folding the flexible substrate.

Moreover, the semiconductor module device further includes land copper foil formed in the flexible substrate so as not to be connected to the wiring, wherein the land copper foil and the semiconductor chip are electrically connected to each other.

The semiconductor module device further includes a tape carrier package having the semiconductor chip mounted on the flexible substrate by one of TAB mounting and face-down mounting.

A method of manufacturing the semiconductor module device according to the present invention includes the steps of: applying, on the flexible substrate, the insulating resist for protecting the wiring; mounting the semiconductor chip on the flexible substrate in a state in which the insulating resist is uncured; bonding the metal foil on at least a part of the surface of the insulating resist and the surface of the chip protecting resin for molding the semiconductor chip, when the chip protecting resin is partially cured after the chip protecting resin is applied to the semiconductor chip; and curing and securing the insulating resist and the chip protecting resin after the bonding step.

A flat panel display according to the present invention includes the semiconductor module device screwed with a fixed clearance.

A plasma display panel includes the semiconductor module device screwed with a fixed clearance.

### BRIEF DESCRIPTION OF THE DRAWINGS

FIG. 1 is a sectional view showing the configuration of a semiconductor module device according to a first embodiment;

FIG. 2 is a part exploded perspective view showing the configuration of the semiconductor module device according to the first embodiment;

FIG. 3 is an external perspective view showing the assembled semiconductor module device according to the first embodiment;

FIG. 4 is a main part enlarged view showing the chassis of a flat display panel according to the first embodiment;

FIG. 5 is a perspective view showing a state in which the semiconductor module device of the first embodiment is mounted on the flat display panel;

FIG. 6 is a perspective view showing the backside of the flat display panel according to the first embodiment;

FIG. 7 is a sectional view showing the configuration of a semiconductor module device according to a third embodiment;

FIG. 8 is a part exploded perspective view showing the configuration of the semiconductor module device according to the third embodiment;

FIG. 9 is an external perspective view showing the assembled semiconductor module device of the third embodiment;

FIG. 10 is an external view showing a tape carrier on which flexible substrates are formed according to the third embodiment;

FIG. 11 is a sectional view showing the configuration of a semiconductor module device according to a fourth embodiment;

FIG. 12A is a process sectional view showing a method of manufacturing the semiconductor module device of the first embodiment;

FIG. 12B is a process sectional view showing the method of manufacturing the semiconductor module device of the first embodiment;

FIG. 12C is a process sectional view showing the method of manufacturing the semiconductor module device of the first embodiment;

FIG. 12D is a process sectional view showing the method of manufacturing the semiconductor module device of the first embodiment;

FIG. 12E is a process sectional view showing the method of manufacturing the semiconductor module device of the first embodiment;

FIG. 13 is a sectional view showing the configuration of a semiconductor module device of the prior art;

FIG. 14 is a part exploded perspective view showing the configuration of the semiconductor module device of the prior art; and

FIG. 15 is an external perspective view showing the assembled semiconductor module device of the prior art.

### DESCRIPTION OF THE EMBODIMENTS

### First Embodiment

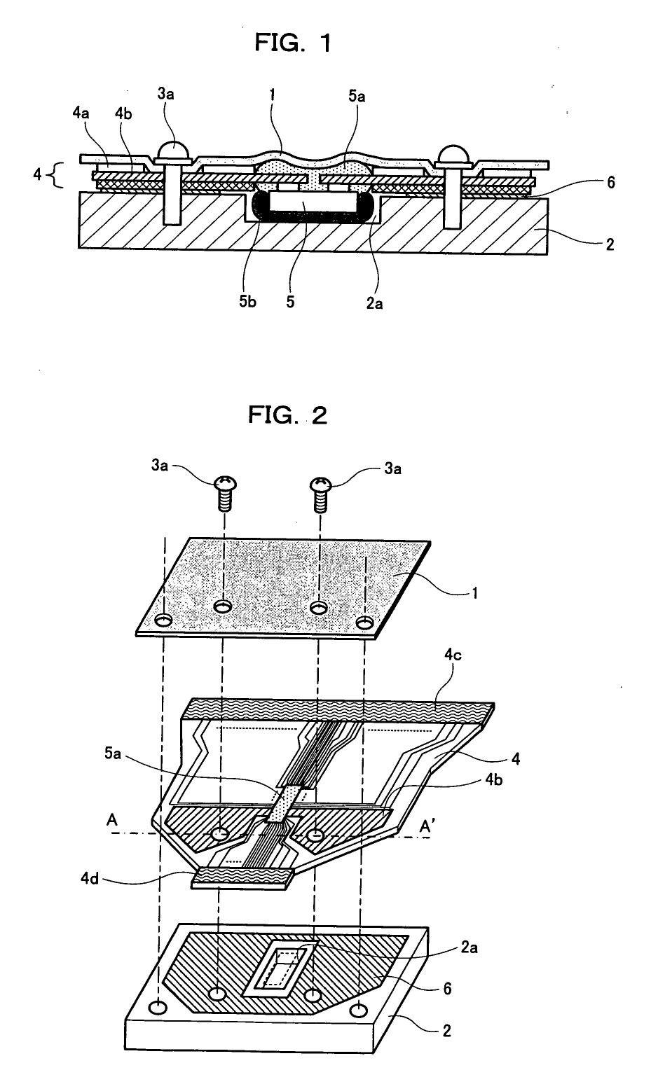

Referring to FIGS. 1 to 6, a heat dissipating structure of a semiconductor module device according to an embodiment of the present invention will be described below.

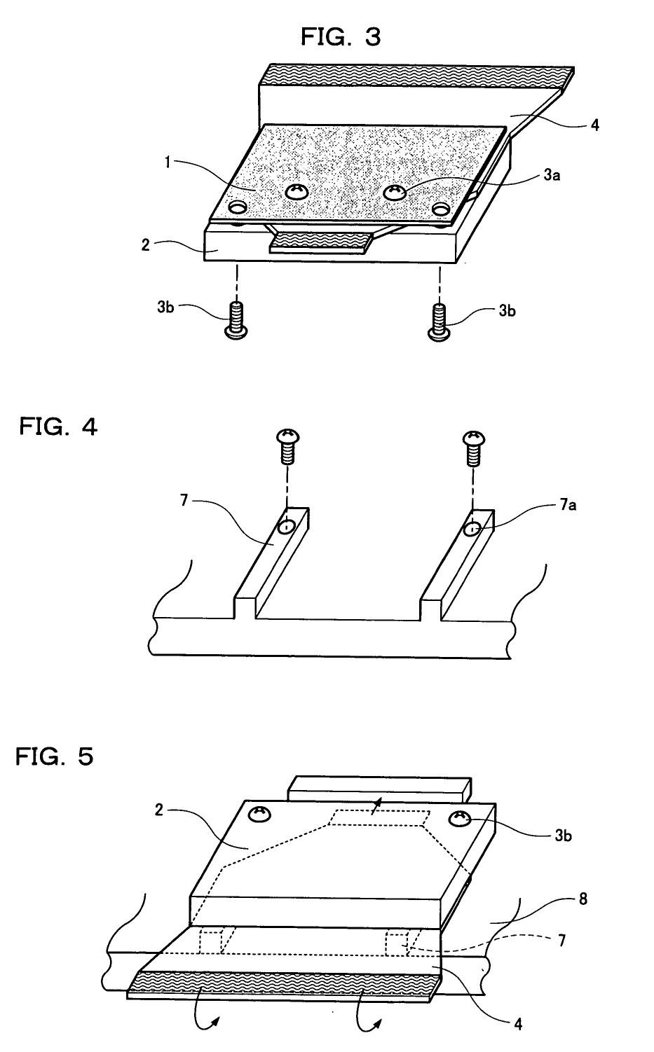

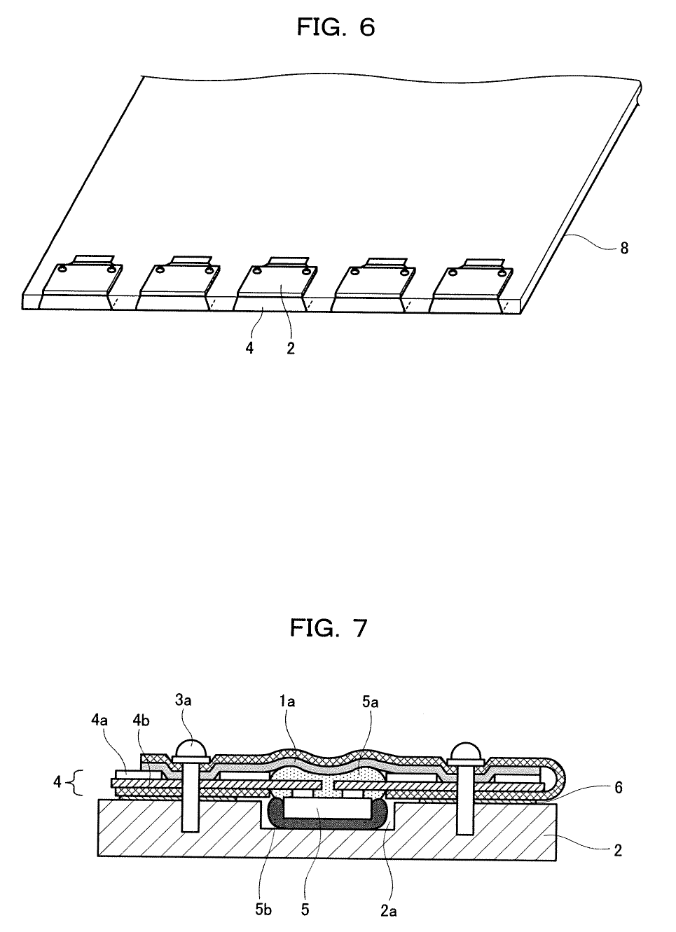

FIG. 1 is a sectional view showing the configuration of the semiconductor module device according to a first embodiment. FIG. 1 shows an assembled state of an exploded view shown in FIG. 2 and is taken along line A-A′ of FIG. 2. FIG. 2 is an exploded perspective view of parts indicating the configuration of the semiconductor module device according to the first embodiment. FIG. 3 is an external perspective view showing the assembled semiconductor module device according to the first embodiment. FIG. 4 is a main part enlarged view showing the chassis of a flat display panel according to the first embodiment and is an enlarged perspective view showing the chassis for supporting the flat display panel of a flat panel display. FIG. 5 is a perspective view showing a state in which the semiconductor module device of the first embodiment is mounted on the flat display panel and a perspective view showing a state in which the single semiconductor module device is attached to the chassis. FIG. 6 is a perspective view showing the backside of the flat display panel according to the first embodiment.

In the semiconductor module device shown in the sectional view of FIG. 1, metal foil 1 is in contact with an insulating resist 4a which is a wiring protecting film of a flexible substrate 4, and is also in contact with the element forming surface of a semiconductor chip 5 via a chip protecting resin 5a. Further, the metal foil 1 is screwed, on positions close to the semiconductor chip 5, to a radiator 2 through land copper foil 4b of the flexible substrate 4 with fastening screws 3a. Since wiring routed from the semiconductor chip 5 to an electrode 4c (see FIG. 2) and an electrode 4d (see FIG. 2) in two directions is vertically divided, the land copper foil 4b is formed as large as possible in a triangle region where the wiring is not routed. At this point, the land copper foil 4b is screwed to the radiator 2 with the fastening screws 3a such that openings are formed on the insulating resist 4a and the metal foil 1 and the land copper foil 4b are in direct contact with each other. Thus the metal foil 1 is fastened while a thermal resistance is minimized in heat transfer to the metal foil 1, the land copper foil 4b, and the fastening screws 3a. Further, by increasing the region of the land copper foil 4b in a heat dissipation path where heat generated on the semiconductor chip 5 is transmitted to the metal foil 1, is diffused on the metal foil 1, is transmitted to the land copper foil 4b, and is released to the radiator 2 via the fastening screws 3a, it is possible to form a path capable of transmitting a larger amount of heat to the fastening screws 3a.

The radiator 2 has the flexible substrate 4 fixed with an adhesive 6 and heat is dissipated from a backside from the element forming surface for the semiconductor chip 5 through a heat dissipating material 5b. FIG. 2 shows an exploded image of parts indicating the configuration of the semiconductor module device. By fastening the flexible substrate 4 to the radiator 2 with the fastening screws 3a, the metal foil 1 and the radiator 2 are connected to each other via the fastening screws 3a. In a state in which the semiconductor module device is assembled (FIG. 3), the diffusion circuit forming surface of the semiconductor chip 5 is directed to the flat display panel and the semiconductor module device is screwed with fastening screws 3b while a clearance is provided between the semiconductor module device and the flat display panel by chassis receiving parts 7 formed on a chassis for fastening the flat display panel of FIG. 4 with the fastening screws 3b. A plurality of semiconductor module devices are mounted thus on the flat display panel (FIG. 6).

The configuration will be described in detail below. The metal foil 1 includes foil composed of a material such as an Al alloy. The metal foil 1 has a thickness of about 25 μm and has to be made of a metallic material enabling contact with the flexible substrate 4 and chip protecting resin 5a with plastic deformation of a low stress. When a certain heat capacity is to be obtained for the metal foil 1, multiple pieces of the metal foil 1 may be stacked (not shown). Further, the metal foil 1 is large enough to cover at least the wiring region of the semiconductor chip 5 and the flexible substrate 4 and include portions where the fastening screws 3a used for fastening the radiator 2 and the metal foil 1 are placed. Moreover, the metal foil 1 has openings which are as large as the diameters of the fastening screws 3a and 3b and are formed on positions where the fastening screws 3a for screwing the flexible substrate 4 and the metal foil 1 are inserted and positions where the fastening screws 3b for screwing the radiator 2 and the chassis receiving parts 7 are inserted.

The radiator 2 is made of a material such as aluminum having a high thermal conductivity. The radiator 2 has a storage recessed portion 2a larger than the semiconductor chip 5, and the semiconductor chip 5 is stored in the storage recessed portion 2a. The semiconductor chip 5 mounted on the flexible substrate 4 fixed on the radiator 2 with the adhesive 6 is held on the bottom of the storage recessed portion 2a filled with the heat dissipating material 5b. The storage recessed portion 2a is an enclosed space surrounded by the semiconductor chip 5, the flexible substrate 4, the radiator 2, the adhesive 6, and the heat dissipating material 5b and thus may include an air vent port (not shown).

The flexible substrate 4 is formed by a flexible resin film made of a polyimide material. On the flexible substrate 4, the semiconductor chip 5 is mounted and is connected to wiring copper foil via bumps and the like. The semiconductor chip 5 has a connected portion with the flexible substrate 4. The connected portion is molded with the chip protecting resin 5a for reinforcement and is electrically insulated from other members.

The flexible substrate 4 further includes wiring (not shown) for connecting the electrodes 4c and 4d and the semiconductor chip 5. The land copper foil 4b in the shape of a sector is provided over the blank region of the flexible substrate 4 so as to avoid the wiring region. The land copper foil 4b is connected to the semiconductor chip 5 via inner leads and is directly connected to the semiconductor chip 5, so that heat generated on the semiconductor chip 5 is dissipated to the fastening screws 3a directly through the land copper foil 4b. Further, the land copper foil 4b is connected to the chassis receiving parts 7 via the fastening screws 3a and thus can be used as a ground terminal. The land copper foil 4b has screw holes for screwing. Moreover, in order to avoid the influence of electromagnetic noise and so on, wires adjacent to the land copper foil 4b include at least an electrically ineffective wire or the wires are sufficiently spaced.

The electrode 4c of the flexible substrate 4 is connected to an electrode formed on a flat display panel 8, via an anisotropic conductive film and the like (FIG. 5). The electrode 4d is connected to an electrode formed on a control board on the flat display panel 8, via a connector and the like (FIG. 5). In FIG. 6, the flat display panel 8 is fixed on a metallic chassis (not shown) and the plurality of semiconductor module devices are respectively provided on the plurality of chassis receiving parts 7 of the flat display panel 8. The semiconductor module devices control the flat display panel 8 through control circuits and cause the flat display panel 8 to display an image.

The following will describe the heat dissipation mechanism of the semiconductor module device according to the present invention. In an actual use of the semiconductor module device, when the semiconductor chip 5 is energized and operated, heat is generated from a surface element on the semiconductor chip 5 and is transferred, in one route, to the metal foil 1 through the chip protecting resin 5a. The heat of the metal foil 1 is transferred to the radiator 2 through the fastening screws 3a and the radiator 2 dissipates the heat to the chassis receiving parts 7 through the fastening screws 3b. Most of the heat is dissipated to the chassis receiving parts 7 forming the clearance and part of the heat is dissipated to an air space. For example, when the wiring material of the flexible substrate 4 is copper having an extremely high thermal conductivity, heat is dissipated onto the flexible substrate 4 through wiring connected to the semiconductor chip 5. On the wiring, the insulating resist 4a for protecting the wiring is applied with a thickness of about 25 μm. Heat is transferred from the wiring to the metal foil 1 through the insulating resist 4a, and then the heat is transferred and dissipated in the above-described manner. For example, when the chip protecting resin 5a is made of an epoxy resin having a low thermal conductivity, the resin has a small thickness of about 100 μm and 90% of heat generated on the semiconductor chip 5 is transferred onto the chip protecting resin 5a.

Another dissipating path of heat generated on the surface element of the semiconductor chip 5 is similar to the path of the example of the prior art. Heat from the surface element of the semiconductor chip 5 is transmitted to the backside of the chip through the substrate of the semiconductor chip 5. For example, when the substrate is made of silicon, the substrate has a small thickness of 625 μm and thus achieves extremely high thermal conduction. Further, the heat having been transmitted to the backside of the semiconductor chip 5 is transferred to the radiator 2 through silicone grease acting as the heat dissipating material 5b or a heat dissipating sheet and the like. The radiator 2 is screwed to the metallic chassis receiving parts 7 with the clearance formed between the radiator 2 and the chassis receiving parts 7 and the heat is dissipated to the chassis. In this case, heat is dissipated from the wiring on the flexible substrate 4 to the radiator 2 with lower heat conduction than heat conduction on the surface of the aforementioned wiring pattern. The flexible substrate 4 is made of a base material such as polyimide and has a thickness of 75 μm. In the wiring copper foil, an adhesive layer for lamination with the polyimide has a thickness of about 12 μm. Thus high heat conduction from the surface wiring of the flexible substrate 4 to the radiator 2 cannot be expected because of the high thermal resistance.

The following is typical thermal conductivities: copper: 390 W·m⁻¹·K⁻¹, aluminum: 236 W·m⁻¹·K⁻¹, silicon: 168 W·m⁻¹·K⁻¹, polyimide resin: 0.044 W·m⁻¹·K⁻¹, epoxy resin: 0.19 W·m⁻¹·K⁻¹.

As described above, the circuit forming surface of the semiconductor chip mounted on the flexible substrate via the chip protecting resin is connected to the metal foil that is provided on the flexible substrate and is connected to the radiator via the fastening screws, and the surface opposed to the element forming surface of the semiconductor chip is connected to the radiator via the heat dissipating material, so that heat from the element forming surface can be transmitted to the radiator through the chip protecting resin, the metal foil, and the fastening screws, and heat from the surface opposed to the element forming surface can be transmitted to the radiator through the heat dissipating material and can be dissipated from the radiator through the chassis receiving parts. Thus it is possible to improve heat dissipation without considerably increasing the number of components and a set weight.

Additionally, since the semiconductor chip is wrapped by the metallic radiator and the metal foil, it is possible to absorb and block electromagnetic radiation noise EMI (electromagnetic interference) generated from the mounted elements of a signal transmitter.

Further, the land copper foil on the flexible substrate screwed to the radiator and the ground terminal of the semiconductor chip are connected to each other, thereby preventing a malfunction and a break of the semiconductor chip when surge current passes through the chip. Consequently, the operational reliability of the semiconductor chip can be obtained.

### Second Embodiment

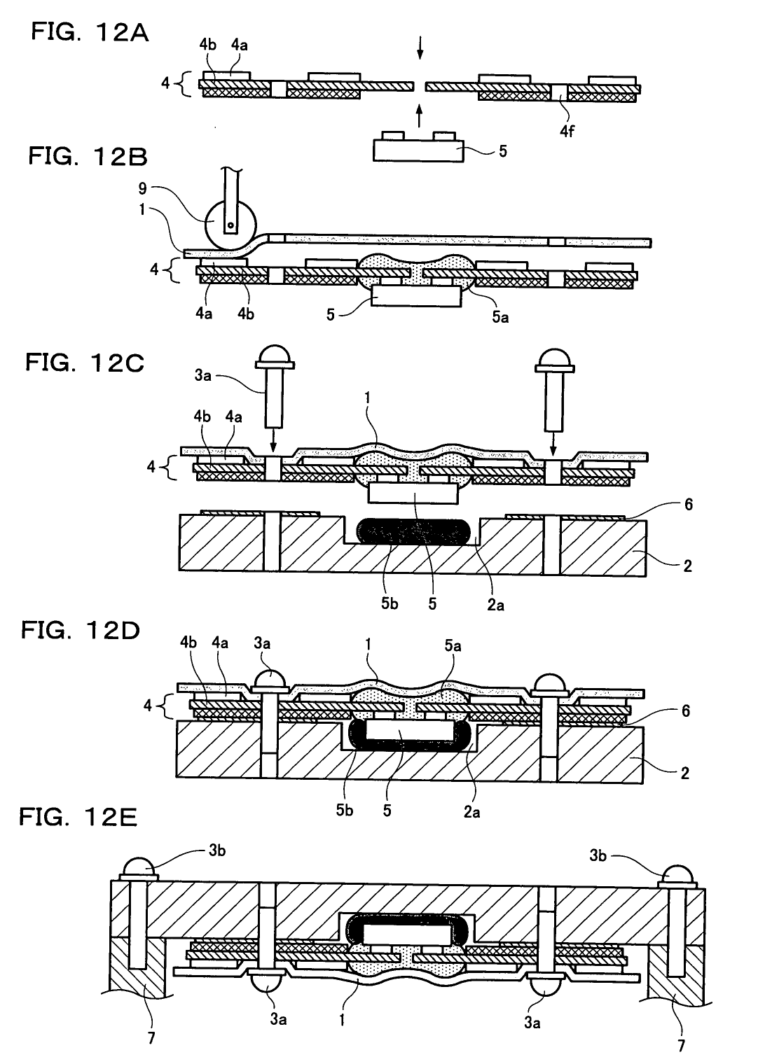

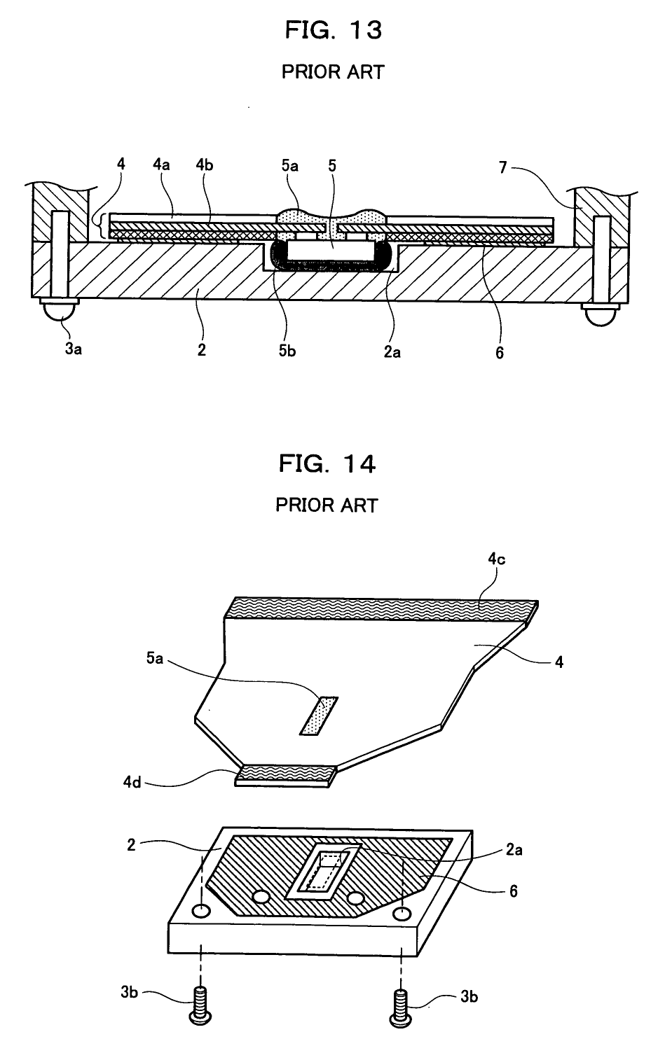

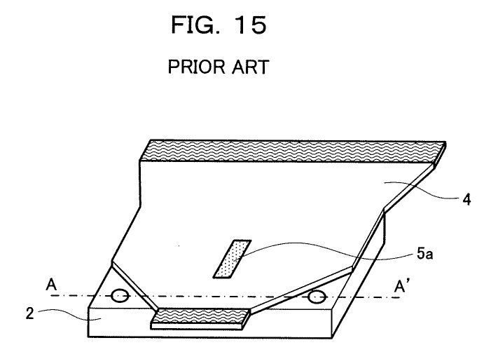

Referring to FIGS. 12A, 12B, 12C, 12D and 12E, the following will describe a method of manufacturing the semiconductor module device described in the first embodiment.

FIGS. 12A, 12B, 12C, 12D and 12E are process sectional views showing the method of manufacturing the semiconductor module device described in the first embodiment.

First, in FIG. 12A, the semiconductor chip 5 is mounted on the flexible substrate 4. In this configuration, the flexible substrate 4 is, for example, a three-layer tape carrier and the semiconductor chip 5 is mounted by tape automated bonding (TAB) in which the semiconductor chip 5 is mounted for each reel while the tape carrier is wound around the reel. A hole for placing the semiconductor chip 5 is formed around the center of the flexible substrate 4, inner lead wiring that is provided in the hole and partially acts as the land copper foil 4b and the electrodes of the semiconductor chip 5 are aligned with each other, and then the semiconductor chip 5 is thermocompression bonded.

Next, in FIG. 12B, the liquid chip protecting resin 5a is applied (not shown) from the top surface of the chip. After the chip protecting resin 5a is applied, the chip protecting resin 5a is cured by applying heat in a curing oven and the application of heat increases the tack of the insulating resist 4a of the flexible substrate 4. In this case, the insulating resist 4a is a resin whose tackiness is restored by overheating after the curing reaction of resist resin is interrupted, and the curing reaction is completed by further applying heat. After the process advances, in a state in which the curing reaction of the resin progresses to a certain level and the surface of the protecting resin still has tackiness, the metal foil 1 is bonded to the top surface of the semiconductor chip 5 and the wiring region of the flexible substrate 4. At this moment, the metal foil 1 is aligned relative to the fastening screw holes for screwing the metal foil 1 and the flexible substrate 4 to the radiator 2, and then the metal foil 1 is bonded to the flexible substrate 4 and the semiconductor chip 5 by means of a rubber rotating roller 9 in a state in which the metal foil 1 is placed on the flexible substrate 4. For example, when the metal foil 1 has a thickness of 25 μm and is made of an aluminum alloy, the metal foil 1 is plastically deformed with ease by a pressure of the rubber rotating roller 9 and is bonded while absorbing the unevenness of the insulating resist 4a and the chip protecting resin 5a on the wiring region. In this state, the chip protecting resin 5a and the insulating resist 4a are passed through the curing oven, so that the curing of the chip protecting resin 5a and the insulating resist 4a is completed. Thereafter, the outside shapes of regions to be used on the flexible substrates 4 are punched into pieces.

In FIG. 12C, the flexible substrate 4 of FIG. 2 is bonded to the radiator 2. In this case, the adhesive 6 is applied around the storage recessed portion 2a of the radiator 2. In the bonding of the flexible substrate 4 and the radiator 2, first, the adhesive 6 is applied to the radiator 2 and the heat dissipating material 5b is applied to the storage recessed portion 2a so as to sufficiently cover the backside of the semiconductor chip 5. Next, the flexible substrate 4 and the radiator 2 are aligned with each other, and the semiconductor chip 5 is brought into contact with the heat dissipating material 5b of the storage recessed portion 2a. Then, a region where the adhesive 6 has been applied is pressed by a rotating roller (not shown) and the like to securely bond the flexible substrate 4 and the radiator 2.

Next, in FIG. 12D, the metal foil 1 and the land copper foil 4b of the flexible substrate 4 are screwed to the radiator 2 with the fastening screws 3a such that the metal surfaces are joined to each other without disposing the insulating resist 4a and so on between the metal surfaces. The fastening screws 3a are disposed around the semiconductor chip 5 and are connected to the semiconductor chip 5 via wiring and the land copper foil 4b, so that heat generated from the chip can be effectively transmitted and connection with a ground terminal in the semiconductor chip 5 enables a grounding function. The basic semiconductor module device is completed in this step.

In FIG. 12E, as a flat display panel, the surface where the metal foil is provided on the flexible substrate 4 of the semiconductor module device is finally directed to the chassis receiving parts 7, and the radiator 2 and the chassis receiving parts 7 are screwed by the fastening screws 3b with a clearance formed between the radiator 2 and the chassis receiving parts 7, so that a heat dissipating structure is completed.

As described above, when the semiconductor module device is manufactured, the light and thin metal foil 1 is added without adding a radiator plate and the like having a complicated configuration, so that heat dissipation and heat transfer are performed with a simple configuration where the semiconductor chip 5 serving as a heat source is sandwiched. Thus it is possible to improve heat dissipation without considerably increasing the number of components or a set weight.

### Third Embodiment

Referring to FIGS. 7 to 10, the following will describe a heat dissipating structure of a semiconductor module device according to a third embodiment of the present invention.

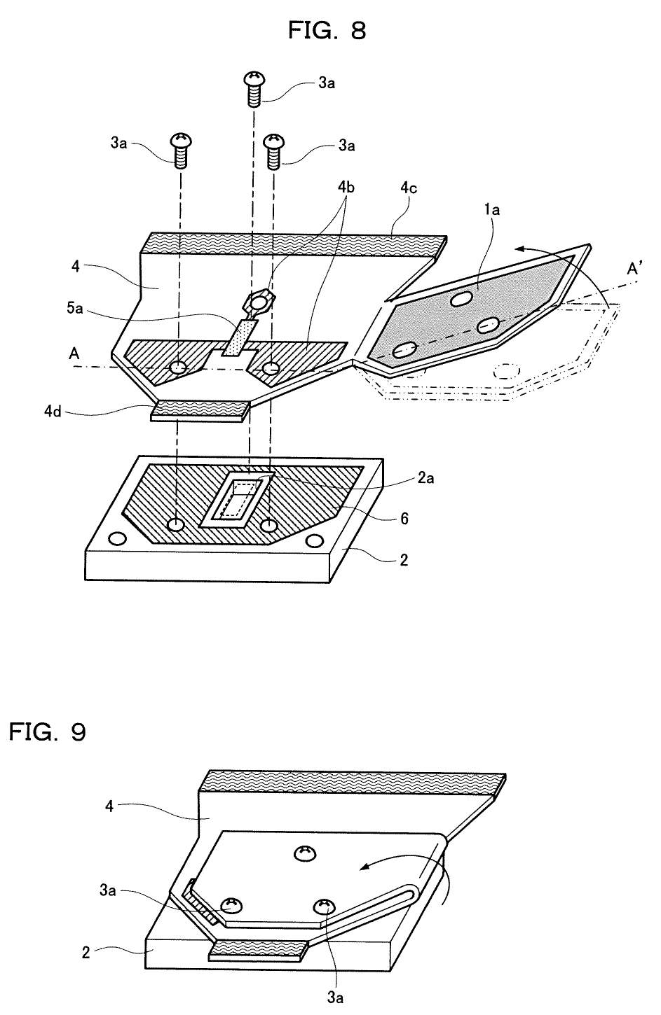

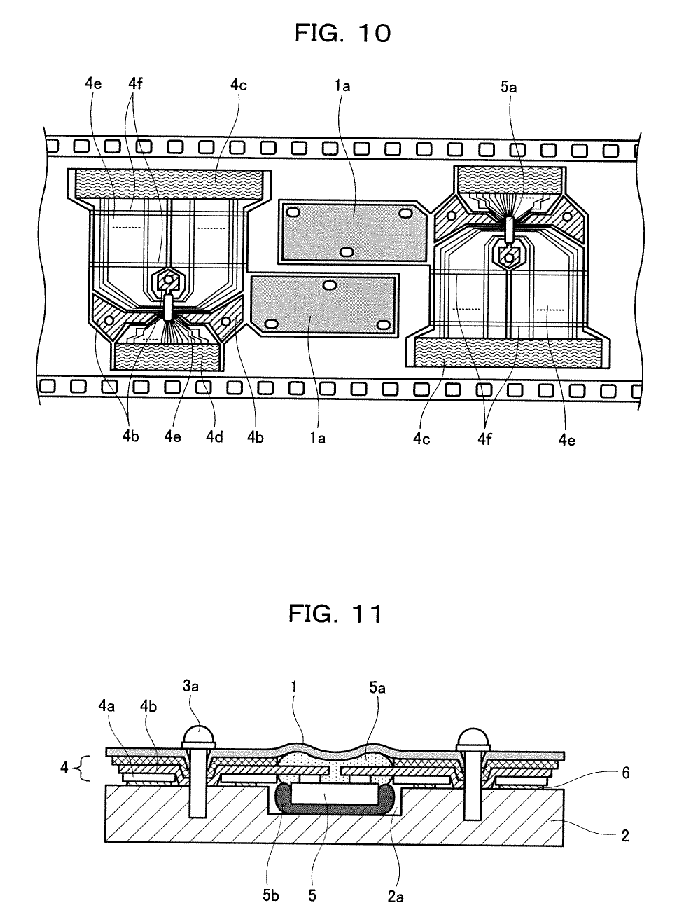

FIG. 7 is a sectional view showing the configuration of the semiconductor module device according to the third embodiment. FIG. 7 shows an assembled state of an exploded view shown in FIG. 8 and is taken along line A-A′ of FIG. 8. FIG. 8 is an exploded perspective view of parts indicating the configuration of the semiconductor module device according to the third embodiment. FIG. 9 is an external perspective view showing the assembled semiconductor module device according to the third embodiment. FIG. 10 is an external view showing a tape carrier on which flexible substrates are formed according to the third embodiment. The semiconductor module device of the present embodiment is identical to the semiconductor module device according to the first embodiment, except for metal foil formed on a flexible substrate 4. The same constituent elements are indicated by the same reference numerals and the explanation thereof is omitted.

In FIG. 7, the flexible substrate in the semiconductor module device of the present embodiment has a region over which copper foil 1a is laid. The region is extended from the flexible substrate of the first embodiment. Instead of the metal foil 1 (see FIG. 1) described in the first embodiment, the same copper foil as wiring for connecting a semiconductor chip 5 and electrodes 4c and 4d on an extension of the flexible substrate 4 is laid over the region having been extended from the flexible substrate, and the copper foil is used as the metal foil (hereinafter, will be referred to as copper foil) 1a. A feature of the present embodiment is that the region over which the copper foil 1a is laid is folded to a surface of the flexible substrate 4, the surface being opposed to a surface connected to a radiator 2, and then the flexible substrate 4 is screwed. This configuration makes it possible to improve heat dissipation without increasing the number of components, as compared with the case where the metal foil 1 is fastened while separated.

FIG. 8 is an exploded perspective view of parts composing the semiconductor module device of the present invention. After the semiconductor chip 5 is mounted on the flexible substrate 4, the plurality of flexible substrates 4 are punched from the tape carrier on which the flexible substrates 4 have been formed. In this state, the flexible substrate 4 is fastened to the radiator 2 with an adhesive 6 as in the first embodiment. Thereafter, the region where the copper foil 1a has been formed on the flexible substrate 4 is folded such that the copper foil 1a is disposed inside the flexible substrate 4 and is brought into contact with semiconductor chip protecting resin 5a, and fastening screws 3a are screwed into the radiator 2 on three points (FIG. 9).

When the copper foil 1a is brought into contact with the semiconductor chip protecting resin 5a, the copper foil 1a is formed on the base substrate of the flexible substrate 4. Thus the unevenness of the chip protecting resin 5a cannot be absorbed. However, the flexible substrate 4 is made of a material such as polyimide having a large elastic force and the chip protecting resin 5a is pressed to the radiator 2 with the elastic force of the base material by screwing, on at least three points, the flexible substrate to the radiator 2 having stiffness. Thus it is possible to obtain sufficient contact and heat dissipation. Similarly, on the screwed portions of land copper foil 4b on the side of the flexible substrate 4 and the copper foil 1a, the base material of the flexible substrate 4 has a large elastic force and thus mechanical stresses applied by the fastening screws 3a enable bonding around the fastening screws 3a. For example, in the flexible substrate 4, the base material is polyimide and has a thickness of 75 μm, metal foil for forming the wiring, the land copper foil, and the copper foil 1a has a thickness of 25 μm, and the base material and the metal foil are laminated with an adhesive having a thickness of 12 μm.

Next, referring to FIG. 10, the flexible substrates 4 according to the first and third embodiments will be described in detail. The plurality of flexible substrates 4 are formed on a tape and are transported on the tape. After the semiconductor chips 5 are mounted on the flexible substrates 4, a plurality of identical wiring patterns are formed on the tape carrier and necessary parts are punched in the final step to form semiconductor module devices. In this case, the tape carrier is a three-layer tape carrier having a width of 70 mm. When the semiconductor chip 5 is rectangular, the semiconductor chip 5 is mounted such that the long sides are, for example, orthogonal to the feed direction of the tape carrier. In the wiring layout of the flexible substrate 4, the electrodes 4c and 4d are laid out along the width direction relative to the feed direction of the tape carrier and are connected to the semiconductor chip 5 via routed wiring 4e. In this wiring layout, outputs are provided in two directions along the electrodes 4c and 4d and thus the wiring can have blank regions on three points on the right and left sides of the chip and above the chip. Therefore, the land copper foil 4b is disposed in the blank regions to add a heat dissipation path. On the top surface of the land copper foil 4b, for example, Sn having a thickness of about 2.0 μm is applied as external plating. The insulating resist 4a on the land copper foil 4b is applied only to the wiring connected and routed from the semiconductor chip 5 and the resist is opened basically without being applied to the region of the land copper foil 4b. The insulating resist 4a is applied to the other routed wiring 4e to securely protect the wiring. Further, folding slits 4f are provided for folding and mounting the flexible substrate 4.

The copper foil 1a on the flexible substrate 4 of the present invention is disposed in the region extended from a side where the semiconductor chip 5 is placed on the flexible substrate 4, while avoiding the folding slits 4f of the flexible substrate 4. The length of the copper foil 1a from the edge of the flexible substrate 4 has to be long enough to reach at least the semiconductor chip 5 when the copper foil 1a is folded. In this configuration, the length of the copper foil 1a is set to reach, when the copper foil 1a is folded, the land copper foil 4b formed on the right and left of the semiconductor chip. Further, Sn is applied as external plating on the copper foil 1a. Moreover, on the copper foil 1a, screw holes for screwing are formed on three points.

Further, in FIG. 10, the adjacent wiring patterns of the present invention are alternately reversed to increase the use efficiency of the tape carrier, thereby reducing a loss in the use of the tape carrier. However, on this tape carrier, the orientations of the chips are alternately reversed when the semiconductor chips are mounted. Thus it is necessary to devise some way for a mounting device. In this case, for example, the semiconductor chips 5 are mounted only in wiring patterns of the same direction so as to skip every other pattern, and then the semiconductor chips are mounted again in the opposite direction. Thus the chips can be mounted without improving an expensive device.

The three-layer carrier is configured such that a 12-μm epoxy adhesive is applied on, for example, a polyimide substrate having a thickness of 75 μm, copper foil having a thickness of 35 μm is laminated thereon, and the insulating resist 4a having a thickness of 25 μm is applied as the top surface to protect the copper foil.

As described above, the copper foil corresponding to the metal foil of the first embodiment is formed in the extended region of the flexible substrate and then the flexible substrate is folded, so that the copper foil is connected to the element forming surface of the semiconductor chip through the chip protecting resin. Thus as in the first embodiment, it is possible to improve heat dissipation without considerably increasing the number of components or a set weight.

### Fourth Embodiment

FIG. 11 is a sectional view showing the configuration of a semiconductor module device according to a fourth embodiment.

The semiconductor module device of the present embodiment is identical to the semiconductor module device of the first embodiment except that a flexible substrate 4 is mounted face down (vertically reversed) on a semiconductor chip 5 and an insulating resist 4a of the flexible substrate 4 is fixed on a radiator 2 with an adhesive 6. The same constituent elements are indicated by the same reference numerals and the explanation thereof is omitted.

In FIG. 11, metal foil 1 is placed on the top surface of the semiconductor chip 5 via chip protecting resin 5a, and the base material surface of the flexible substrate 4, for example, polyimide is in contact with the metal foil 1.

Since the metal foil 1 and the insulating resist 4a do not act as adhesive, fastening screws 3a press the base material surface of the flexible substrate 4 and plastically deform the metal foil 1 so as to fasten the metal foil 1 in contact with the chip protecting resin 5a. Since a heat dissipation path from the metal foil 1 to the fastening screws through land copper foil is reduced, heat conduction from the backside of a surface where the semiconductor chip 5 is mounted on the flexible substrate 4 is lower than heat conduction from the surface where the semiconductor chip 5 is mounted. Thus in the present embodiment, heat is mainly dissipated from the top surface of the semiconductor chip 5 to the metal foil 1. As a heat dissipation mechanism, heat can be dissipated to chassis receiving parts 7 through the radiator 2 as in the first embodiment.

FIG. 11 shows an example of the flexible substrate 4 having three layers (base material, adhesive, copper foil). Also when a flexible substrate having two layers (base material, copper foil) is used and the semiconductor chip 5 is mounted face down, a heat dissipating effect can be expected by placing the metal foil 1 on the flexible substrate (not shown). However, in this case, the two-layer substrate has a thickness of 38 μm, the chip protecting resin having a thickness of about 15 μm to 25 μm is disposed between the semiconductor chip 5 and the flexible substrate, and an adhesive and the like are necessary for bonding the metal foil 1 to the backside of the flexible substrate. Thus the three-layer flexible substrate is better in terms of heat conduction and heat dissipation efficiency.

As described above, the element forming surface of the semiconductor chip mounted on the flexible substrate via the chip protecting resin is connected to the metal foil that is provided on the flexible substrate and is connected to the radiator via the fastening screws, and the surface opposed to the element forming surface of the semiconductor chip is connected to the radiator via a heat dissipating material, so that heat from the element forming surface can be transmitted to the radiator through the chip protecting resin, the metal foil, and the fastening screws, and heat from the surface opposed to the element forming surface can be transmitted to the radiator through the heat dissipating material and can be dissipated from the radiator through the chassis receiving parts. Thus it is possible to improve heat dissipation without considerably increasing the number of components or a set weight.

In the foregoing explanation, a plasma display panel is used as a flat panel display. The present invention is also applicable to other flat panel displays.

Further, in the method of manufacturing the semiconductor module device according to the third and fourth embodiments, as in the second embodiment, the insulating resist and the chip protecting resin are bonded to one of the metal foil and the copper foil before curing, and then the insulating resist and the chip protecting resin are cured.

What is claimed is:

1. A semiconductor module device having a heat dissipating structure, the semiconductor module device comprising:
a flexible substrate on which a wiring pattern connected to an external terminal is formed;
an insulating resist for protecting wiring;
a semiconductor chip mounted on the flexible substrate while molded with chip protecting resin so as to be electrically connected to the wiring pattern;
metal foil formed in contact with the chip protecting resin for molding the semiconductor chip and with at least a part of the insulating resist;
a radiator which has a storage recessed portion and is bonded to the flexible substrate so as to connect the semiconductor chip to the storage recessed portion via a heat dissipating material; and
screws for screwing the metal foil and the radiator with thermal bonding.

2. The semiconductor module device according to claim 1, further comprising a region electrically isolated from the wiring pattern, on a same surface as the wiring pattern of the flexible substrate,
wherein the metal foil is disposed in the region, and
the metal foil is bonded on the chip protecting resin for molding the semiconductor chip and on at least the part of the insulating resist by folding the flexible substrate.

3. The semiconductor module device according to claim 1, further comprising land copper foil formed in the flexible substrate so as not to be connected to the wiring,
wherein the land copper foil and the semiconductor chip are electrically connected to each other.

4. The semiconductor module device according to claim 2, further comprising land copper foil formed in the flexible substrate so as not to be connected to the wiring,
wherein the land copper foil and the semiconductor chip are electrically connected to each other.

5. The semiconductor module device according to claim 1, further comprising a tape carrier package having the semiconductor chip mounted on the flexible substrate by one of TAB mounting and face-down mounting.

6. The semiconductor module device according to claim 2, further comprising a tape carrier package having the semiconductor chip mounted on the flexible substrate by one of TAB mounting and face-down mounting.

7. A method of manufacturing the semiconductor module device according to claim 1, comprising the steps of:
applying, on the flexible substrate, the insulating resist for protecting the wiring;
mounting the semiconductor chip on the flexible substrate in a state in which the insulating resist is uncured;
bonding the metal foil on at least a part of a surface of the insulating resist and a surface of the chip protecting resin for molding the semiconductor chip, when the chip protecting resin is partially cured after the chip protecting resin is applied to the semiconductor chip; and
curing and securing the insulating resist and the chip protecting resin after the bonding step.

8. A method of manufacturing the semiconductor module device according to claim 2, comprising the steps of:
applying, on the flexible substrate, the insulating resist for protecting the wiring;
mounting the semiconductor chip on the flexible substrate in a state in which the insulating resist is uncured;
bonding the metal foil on at least a part of a surface of the insulating resist and a surface of the chip protecting resin for molding the semiconductor chip, when the chip protecting resin is partially cured after the chip protecting resin is applied to the semiconductor chip; and
curing and securing the insulating resist and the chip protecting resin after the bonding step.

9. A flat panel display comprising the semiconductor module device according to claim 1, the semiconductor module device being screwed with a fixed clearance.

10. A flat panel display comprising the semiconductor module device according to claim 2, the semiconductor module device being screwed with a fixed clearance.

11. A plasma display panel comprising the semiconductor module device according to claim 1, the semiconductor module device being screwed with a fixed clearance.

12. A plasma display panel comprising the semiconductor module device according to claim 2, the semiconductor module device being screwed with a fixed clearance.
